(19) United States
(12) Patent Application Publication
(10) Pub. No.: US 2008/0185034 A1
(43) Pub. Date: Aug. 7, 2008

(54) Fly's Eye Lens Short Focal Length Solar Concentrator

(76) Inventor: Ronald P. Corio, Albuquerque, NM (US)

Correspondence Address: DENNIS F ARMIJO, 6300 MONTANO RD. NW, SUITE D, ALBUQUERQUE, NM, 87120, US

(21) Appl. No.: 12/023,188

(22) Filed: Jan. 31, 2008

Related U.S. Application Data
(60) Provisional application No. 60/898,989, filed on Feb. 1, 2007.

(51) Int. Cl. H01L 31/052; H05K 3/34

(52) U.S. Cl. 136/246; 29/840

(57) ABSTRACT

A compact solar concentrator photovoltaic module assembly includes a plurality of rear contact solar cells configured in a matrix array on a substrate. The substrate is comprised of conductors laminated to an insulator sheet to form a receiver sheet. A lens sheet on which many lenses have been formed is disposed in a fixed spaced relation to the substrate and operates to focus sunlight onto the active surfaces of the PV cells. The overall thickness of the concentrator module is less than four inches thick. The receiver sheet may be assembled using standard, surface mount printed circuit board assembly techniques. The receiver sheet may have a secondary optical element and may also serve as part of the encapsulant for environmental protection.

### CROSS REFERENCE TO RELATED APPLICATIONS

This application is based on U.S. Provisional Application Ser. No. 60/898,989 entitled “Fly's Eye Lens Short Focal Length Solar Concentrator”, filed on Feb. 1, 2007, the teachings of which are incorporated herein by reference.

### BACKGROUND OF THE INVENTION

1. Field of the Invention (Technical Field)

The present invention relates to photovoltaics (PV) and more specifically to concentrator photovoltaic modules and methods for making same.

2. Background Art

Photovoltaic cells were first developed in the 1950's and successfully deployed in space applications. Since PV's success in space, terrestrial applications for PV have been steadily increasing. Initial applications for terrestrial PV were in remote areas where traditional sources of energy were not feasible. The terrestrial PV market was relatively small, mostly due to the relatively high cost of PV modules and systems. In the last 5 years there has been large growth in the terrestrial PV market, spurred on by governmental incentive and feed-in tariff laws triggered by global fossil fuel energy supply concerns and environmental issues such as global warming, associated with fossil fuel consumption.

The two most common methods of deploying PV cells into solar electric modules are in a planar, flat-plate module configuration and concentrator designs. The flat-plate design requires that the active area of the collector is equal to the PV material exposed to one sun radiation. There is a one-to-one ratio of active collector area to PV cell area. The cost of a one-sun flat plate module is mostly governed by the cost and efficiency of the PV material that is used to cover the active module area. Therefore, in order to reduce the cost of a flat-plate module, the PV base material must be made less expensive, or more efficient, or both. Many organizations are investigating thin-film photovoltaic technologies to address the issue of lowering the cost of the PV base material. All thin-film approaches thus far have lowered the cost of the PV material at the expense of module efficiency.

In a concentrator arrangement, smaller area solar cells receive concentrated light from an optical element or combination of optical elements. The concentration ratio (active area of collector: active area of PV material) in these designs may vary from 1.5:1 to over 1500:1. Traditionally, design approaches for concentrating collectors have been bulky, using Fresnel lenses or large area reflectors, both of which require long focal lengths and highly accurate solar tracking mechanisms. There have been some recent advances in optical systems for high concentration solar collectors, 250× or higher, using casegrain optics. Casegrain collector designs incorporate multiple, optical elements including mirrored reflectors to achieve a short focal length and large acceptance angle. The elaborate optics of casegrain concentrator designs presents a challenge for low-cost commercialization.

The prior art includes U.S. Pat. No. 4,834,805, Photovoltaic Power Modules and Methods for making Same, issued May 30, 1989 that describes a short focal length concentrator module incorporating standard PV cells with front and rear electrically-conductive material, as show in FIG. 1. The solar cell is sandwiched inside the receiver'sheet material. Silicon photovoltaic material 10 is disposed between rear metallization material 12, which is the positive conductor, and front metallization material 14, which is the negative conductor, containing metallization grid 16. This design incorporates standard solar cells that have conductors applied through a screen-printing process on the front and rear surfaces of the solar cell. In actuality, the aforementioned patent requires a vapor-deposited front side conductor on the solar cell so as not to obscure too much of the active area of the solar cell, and to conduct the higher current densities created by concentration. Front side vapor-deposited metallization increases the cost of the solar cell, and reduces the efficiency of the cell by obscuring the concentrated sunlight. By sandwiching the solar cell into the laminated substrate, the prior art also creates an air void around the solar cell. This air pocket is subject to environmental forces such as thermal and humidity cycling that may lead to premature failure. Further, this design with a front surface metallization grid on the PV cell still masks a significant portion of the photoactive surface of the cell, thus decreasing the efficiency of the power module.

Presently, solar concentrators use Fresnel lenses or reflectors both in linear and point focus designs. Most of these approaches require long focal lengths that create bulky systems with excess materials and weight, or if the designs attain a short focal length with a relatively large solar cell, they require elaborate and expensive optics. The state of the art also requires extra heat dissipative devices to remove heat from the solar cell since the solar cell area is large and a large amount of heat must be removed over longer distances. In the present invention, there is an intense integration of component functions that eliminate heat dissipative devices, long focal lengths and expensive optics.

Another prior art device is described in U.S. Pat. No. 7,297,865, entitled Compact Micro-Concentrator for Photovoltaic Cells, issued Nov. 20, 2007. This patent employs micro reflectors to concentrate sunlight onto small solar cells. The device uses primary reflective optics rather than primary refractive optics as in the present patent application. This design makes little reference to heat dissipation of the cell, cell interconnection method, or module assembly techniques.

The state of the art approaches have not adequately addressed the issues of optical efficiency, optical cost, heat dissipation, solar tracking tolerance and size and weight concerns. Furthermore, the state of the art has not addressed the problem of series connection of modules in a PV system.

### SUMMARY OF THE INVENTION (DISCLOSURE OF THE INVENTION)

The solution to the shortcomings of the prior art is to use small lens elements concentrating onto small high-efficiency rear contact solar cells. With small lens elements formed into a sheet, concentrating onto small PV cells dispersed over the entire module area, the required focal length is short. Additionally, heat dissipation from many small PV cell sites is efficient and economically attained.

A further benefit of the aspects of the present invention is that the lens efficiency is very high since there are no Fresnel facets to obscure light transmission. Fresnel optics are usually employed to decrease the thickness of a lens and thereby save material at the expense of efficiency. In the embodiments disclosed in the present invention, the lens elements are relatively small allowing for a high efficiency lens that is relatively thin, which minimizes the lens material. The integration of this lens design with rear contact PV cells, as opposed to front and back contact PV cells, allows for higher concentration, higher efficiency and simple, automated assembly techniques. The rear contact PV cells may be soldered to a standard surface mount printed circuit board or similar substrate (receiver sheet) using well-known robotic assembly and soldering methods. The PV cells, in combination with the receiver sheet, may then be encapsulated for environmental protection. This receiver sheet assembly may also be encapsulated with a small secondary lens over each PV cell to further enhance the acceptance angle, relaxing the tracking accuracy requirements. The secondary lens element also improves the light distribution received by the PV cell from the primary optical element.

When concentrating sunlight onto a PV cell, there is an increase in temperature accumulation at the cell. Higher temperatures lead to decreased cell efficiency. The present design, with point focus optics and a plurality of small PV cells dispersed onto a large receiver sheet, allows the heat to be effectively dissipated without the use of auxiliary cooling devices.

Through the use of rear contact PV cells, the aspects of the present invention eliminates the solar cell metalization inefficiencies and other problems associated with sandwiching a PV cell into a front-and-back contact receiver sheet. The rear contact solar cell can be mounted on the surface of a substrate instead of sandwiched between two conductors. The receiver sheet substrate requires only a top surface circuit conductor that may be formed using standard printed circuit board manufacturing methods. The substrate of the receiver-sheet may be made from thermally conductive, non-electrically conductive material such as fiberglass, G-10 epoxy board, glass, ceramic, etc.

In the prior art, sandwiching small solar cells into a receiver sheet can lead to shorting across the solar cell; mechanical problems associated with expansion and contraction of the air space around the solar cell; as well as moisture condensation or intrusion into the void around the solar cell. Rear contact solar cells are also more efficient by design and more efficient in this application since there are no grid lines to obscure the concentrated sunlight. Standard front and back side metalized single crystal silicon solar cells are typically 16 to 18% efficient. Rear contact solar cells are typically 22% efficient or more and perform better under concentration than standard PV cells.

The large number of solar cells in the module of the embodiments of the present invention allows for many combinations of series and parallel connections of the solar cells; therefore, many voltage/current possibilities are available within the module, including high-voltage output that is tailored to a system's operation voltage.

Most modern flat plate PV modules employ only 72 solar cells connected in series to achieve a nominal operation voltage between 24-50 volts. All the PV cells within a flat plate module are typically series connected. These modules are then connected in series with other modules in a system to form a higher voltage circuit to reduce I²R wire losses in a solar field, where I represents current and R represents resistance. This module series connection scheme creates a loss factor for the system.

For example, in high-voltage grid-connected systems using typical solar modules with a + or −10% output power range, 10 or more modules are connected in series. The weakest or lowest output module in the series string limits the output of the rest of the series string, resulting in reduced efficiency. In a 10 module series string system, where nine modules generate 200 watts, and one module generates 180 watts, the output of the string is limited to 10×180 or 1800 watts. In parallel, they would produce (9×200 w)+180 w=1980 watts. In this example, 9% of the power is lost in the series connected module string.

Furthermore, any shading, bird droppings, dirt accumulation, premature aging, poor electrical connection, or failure of one module in a string affects the output of the entire string, an important consideration, given that these systems are built to operate in excess of twenty years.

### BRIEF DESCRIPTION OF THE DRAWINGS

The accompanying drawings, which are incorporated into and form a part of the specification, illustrate several embodiments of the present invention and, together with the description, serve to explain the principles of the invention. The drawings are only for the purpose of illustrating a preferred embodiment of the invention and are not to be construed as limiting the invention.

FIG. 1 shows a prior art short focal length concentrator PV cell.

FIG. 2 depicts an aspect of the new solar cell.

FIG. 3 shows the receiver sheet assembly of an aspect of the present invention.

FIG. 4 shows the concentrator assembly of an aspect of the present invention.

FIG. 5 shows the cutaway view of the completed assembly in a frame.

FIG. 6 shows the PV cells connected in parallel.

FIG. 7 shows the PV cells connected in series.

FIG. 8 depicts an aspect of the new power module assembly with secondary lenses.

FIG. 9 shows a blown up view of an aspect of the receiver sheet with secondary lenses.

FIG. 10 shows the concentrator assembly off axis light collection using secondary internal reflection lenses.

### DESCRIPTION OF THE PREFERRED EMBODIMENTS

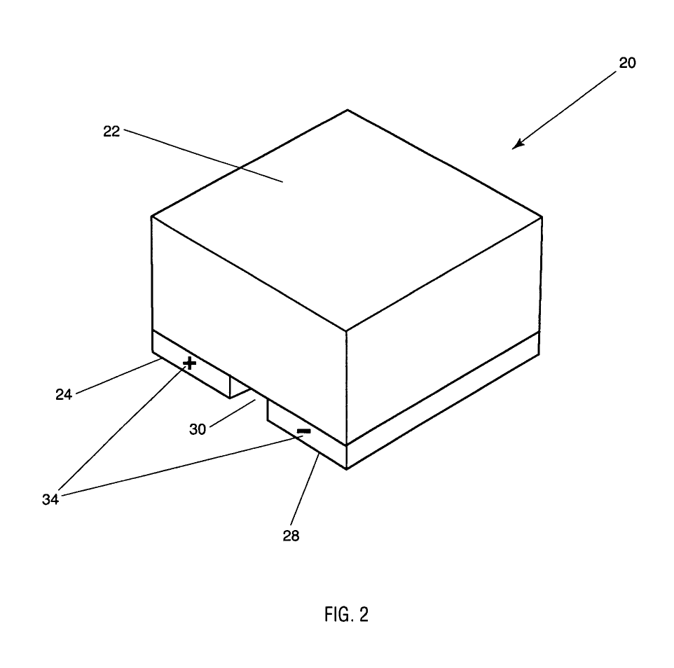

As shown in FIG. 2, solar cells used in the assembly of one aspect of the present invention are pre-fabricated rectangular or square photovoltaic semiconductor crystal wafers or PV cells 20 having a photoactive top surface 22 and a dual electrode conductive rear surface 34. Each wafer may be approximately 25 millimeters square and fabricated from material such as silicon, known to have photovoltaic properties.

Bonded both mechanically and electrically to the rear cell conductive surface 34 are two rear conductors, one positive 24 and one negative 28, which are separated by a void 30 in the conductive surface 34 and readily permits the cell to be electrically joined to printed circuit laminate substrate portion of the module.

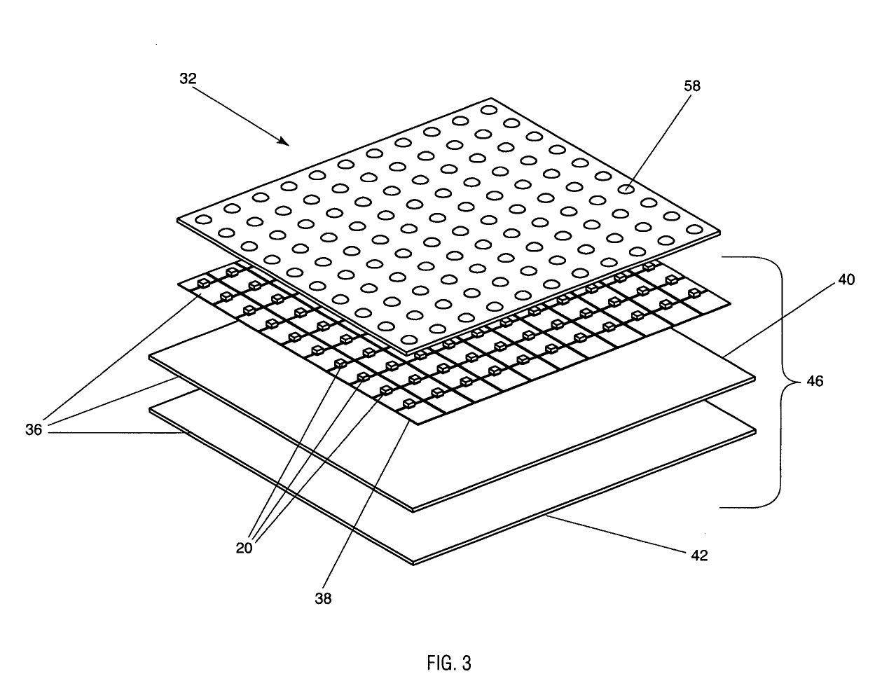

FIG. 3 shows the receiver sheet assembly of a power module of an aspect of the present invention. Receiver sheet assembly 32 includes a plurality of photovoltaic (PV) cells 20, electrically and mechanically disposed on the top surface of laminate substrate structure 36. Laminate substrate 36 comprises a top conductive layer 38 and an insulator layer 40. An optional back conductive layer 42 may be added to laminate substrate 36 to increase the thermal dissipative properties. Each PV cell 20 is mechanically and electrically affixed to top conductive layer 38. Top conductive layer 38 may be constructed from copper as in a printed circuit board. Positive conductors 24 and negative conductors 28 of the PV cells 20 may be electrically connected in series or parallel to other PV cells 20 in the power module through the design of the printed circuit layer 38 of laminate substrate 36 and the advantageous orientation of PV cells 20 onto printed circuit laminate layer 38.

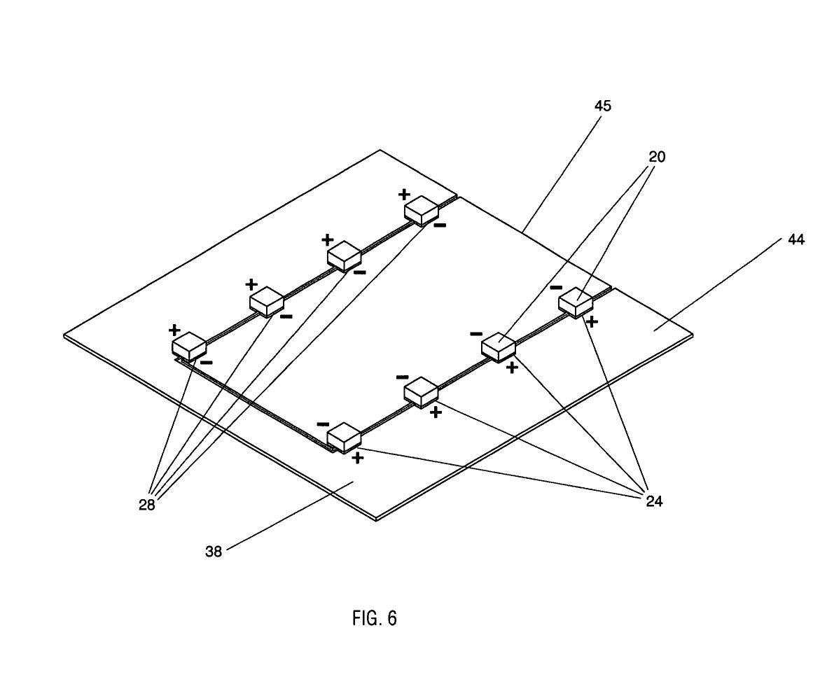

FIG. 6 shows a plurality of PV cells 20 connected in parallel. In this embodiment negative conductors 28 are electrically connected to negative conductive path 45 and positive conductors 24 are electrically connected to positive conductive path 44, of top conductive layer 38, as shown.

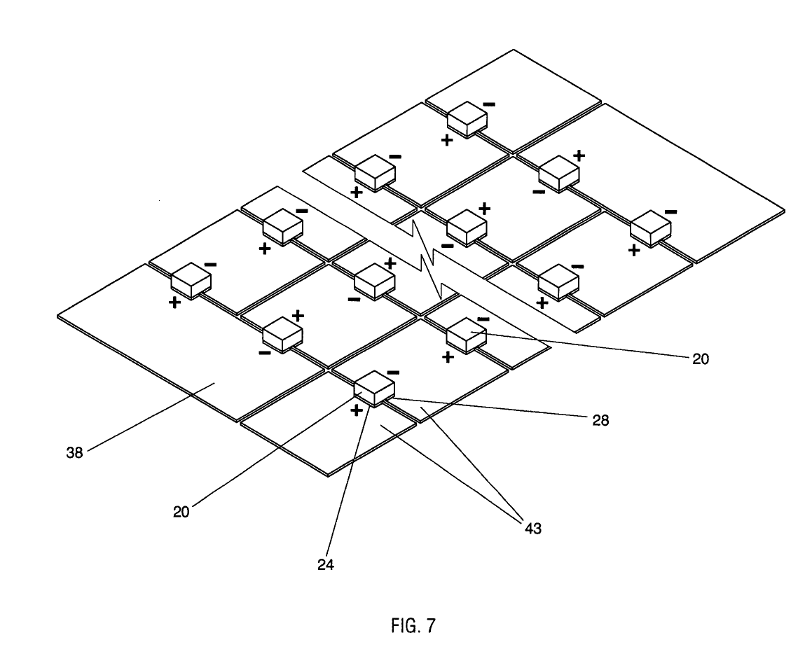

FIG. 7 shows a plurality of PV cells 20 connected in series. For a series connected group of PV cells 20, top conductive layer 38 has many short conductive paths 43 which are electrically affixed to positive conductor 24 of one PV cell 20 and negative conductor 28 of an adjacent PV cell to form the series electrical connection between PV cells.

A group of series connected PV cells, as shown in FIG. 7, may then be connected in parallel with another group of series connected cells within the printed circuit top layer of the receiver sheet to achieve the desired voltage/ampere output of the power module. The plurality of PV cells 20 within power module 32 in conjunction with large possibilities of series and parallel connections of PV cell conductors 24 and 28 allows for extreme flexibility in the power module voltage output. The voltage output of a typical silicon PV cell is in the range of 0.6 volts. The typical output voltage configuration of PV power modules in a solar power plant can range up to 1,000 volts. The large number of PV cells 20 in the disclosed aspects of the present invention allows for a single power module to be configured to the voltage requirement of the entire system voltage. A high voltage power module will decrease the I²R interconnection losses for a field installation. Also, all the modules in a field installation may be connected in parallel, eliminating the aforementioned losses associated with series connected modules.

The mechanical and electrical bonding of PV cells 20 to laminate substrate 36 is similar in fabrication and assembly to a surface mounted printed circuit board. Insulator layer 40 of laminate substrate 36 maintains structural support and electrical separation for printed circuit top layer 38. When photons are received by the active surface 22 of PV cells 20, and electric potential is established between the PV cell positive conductor 24 and negative conductor 28 making the module an electrical power source.

For a PV wafer 25 millimeters square, printed circuit conductors 38 of laminate substrate 36 are formed from copper foil as thick as 5 millimeters and as thin as 1 millimeter while electrical insulator 40 thickness may be determined by the structural, electrical and thermal conductive properties of the material-used for the insulator. A practical range of insulator thickness may be 0.5 millimeters to 4 millimeters thick.

Because the dimensions of PV cell 20 are so small, heat generated within the cell has only a short distance to travel before reaching the surrounding printed circuit board conductors 24 and 28, these conductors are good conductors of heat as well as electricity and thus serve the dual purpose of providing and electrical circuit and an efficient means for heat dissipation. In conventional concentrator power modules, relatively large size PV cells are-exposed to concentrated sunlight and heat generated in the PV cell cannot be dissipated quickly enough to prevent significant heat buildup and resultant efficiency loss, therefore they require auxiliary cooling means. The small size and distributed arrangement of PV cells 20 in the disclosed aspects of the present invention results in sufficient cooling by conduction and convection to permit significant concentration of solar radiation at high efficiencies without requiring auxiliary cooling apparatus.

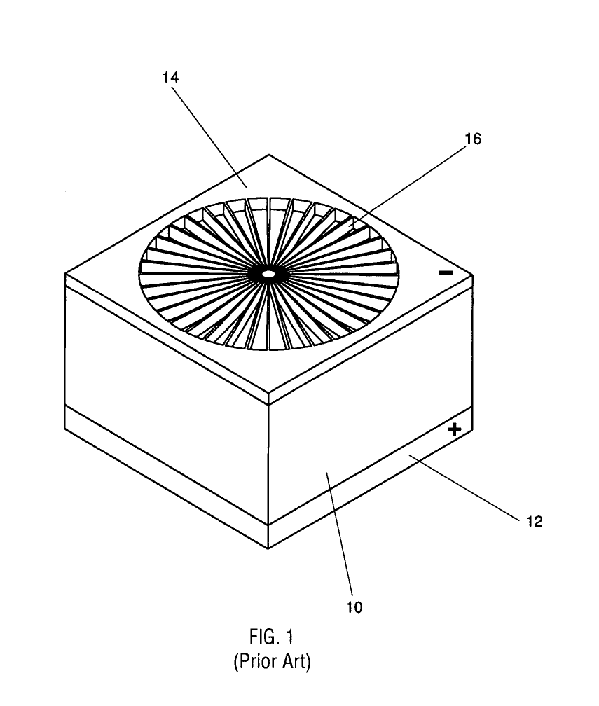

Although the dimensions contemplated for the disclosed aspects are small in terms of heat transfer, they are not insignificant when considering electron travel in the relatively high resistant surface of the PV crystals. A well known technique to reduce the distance the electrons must travel in common front and back conductive surface silicon PV cells is to overlay a top conductor grid onto the photo active top surface of the PV cell, as shown in FIG. 1. Although this top surface conductor grid technique reduces the I²R losses within the PV cell, there is a reduction in radiation received by the PV cell due to the grid shading the photoactive area of the PV cell. This shading affect is increased in the concentrator cell since the current density within the conductors is higher, requiring larger and closer spaced conductors in the grid. Also, many concentrator PV cells require more expensive vapor deposition metallization to be employed for the top grid conductor to help minimize the shading and I²R losses in the conductor. Rear conductor PV cells do not require front surface metallization and therefore do not suffer losses due to conductor grid shading. Rear conductor or rear contact PV cells, are also more efficient under one sun and concentrated radiation than standard front and back contact silicon PV cells which makes them advantageous for the presently disclosed aspects. Rear contact PV cells are typically slightly more expensive to manufacture, but since the disclosed aspects of the present invention uses significantly less PV cells than one-sun modules to generate power, the increased cell cost is insignificant as compared to the increase in efficiency of the power module.

Laminate substrate 36 including PV cells 20 is formed according to the following method. An array of cells 20 is arranged in a grid-like matrix onto printed circuit conductor 38 of laminate substrate 36 that is copper, 1-5 mils thick. Printed circuit conductor 38 is formed using standard printed circuit board manufacturing techniques. A solder paste is screened onto printed circuit conductor 38 in the shape of two pads at each of the PV cell sites and the pads correspond to the positive conductor 24 and negative conductor 28 of PV cells 20. A liquid dot of adhesive is robotically applied to the center of the PV cell site. A pick and place machine picks up PV cell 20 and places it into position. The robotic pick and place equipment incorporates a vacuum probe to pick up individual cells from the diced wafer, then tests each cell, and places the tested cell either onto laminate substrate 36 or into a reject bin based upon the tested characteristics of the cell. The hollow probe of the pick and place equipment includes a light source to illuminate the cell and electrical contacts to measure cell output during the testing process. This testing process may also be used to closely match cells and group PV cells onto the substrate advantageously such that each group of series connected PV cells are closely matched within a module to achieve highest efficiency. The liquid adhesive dots applied to the substrate hold the PV cells in position during the cell assembly operation and into to the soldering operation.

The assembled PV cell/laminate substrate or receiver sheet assembly 46 is then placed into a conveyorized re-flow soldering oven commonly used for surface mount technology (SMT) printed circuit boards. The SMT conveyorized soldering oven consists of four temperature zones. The first zone is a pre-heat zone that gradually increases a receiver sheet assembly 46 temperature to minimize thermal shock damage. The second zone is a thermal soak zone, which allows removal of solder paste volatiles and activates the flux in the solder paste. Receiver sheet assembly 46 should reach thermal equilibrium at the end of this stage. The third zone in this process is called the re-flow zone and is where the peak temperature of the process is reached. The solder paste is becomes liquid in this zone and the flux reduces surface tension at the juncture of the metals to accomplish metallurgical bonding, allowing the individual solder powder spheres in the solder paste to combine with the metalized rear contacts of the PV cell. The last zone is the cooling zone to gradually cool reciever sheet assembly 46 and solidify the solder joints. Soldered reciever sheet assembly 46 will then go through a cleaning process to remove any residual flux left from the soldering process.

An advantage of using printed circuit conductors constructed from a thin foil of copper in the reciever assembly is that in operation, the laminate will experience significant temperature cycling between high temperatures when there is abundant solar energy and low temperatures during the night. This temperature cycling may normally be a source of fatigue in the electrical connections. Because the electrical connections are made of thin foil conductors in the disclosed aspects which are inherently flexible, the stress in the electrical connections is minimized. The reciever sheet assembly electrically connects all of the cells without the use of any wires, thus giving the reciever sheet the electrical integrity found in surface mount printed circuit board assemblies.

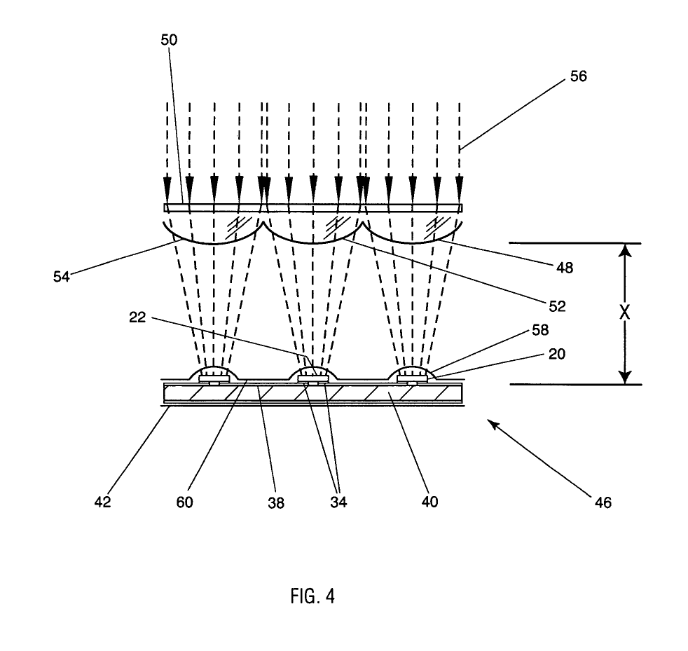

FIG. 4 shows the concentrator assembly of an aspect of the invention. Reciever sheet 46 presents an array of exposed photo active PV cell surfaces 22 which when illuminated with sunlight 56 will generate an electrical current. To make the most efficient use of each cell active surface 22, a concentrating primary lens sheet 48 is provided to to receive sunlight 56, concentrate it and focus it onto each cell's active surface 22.

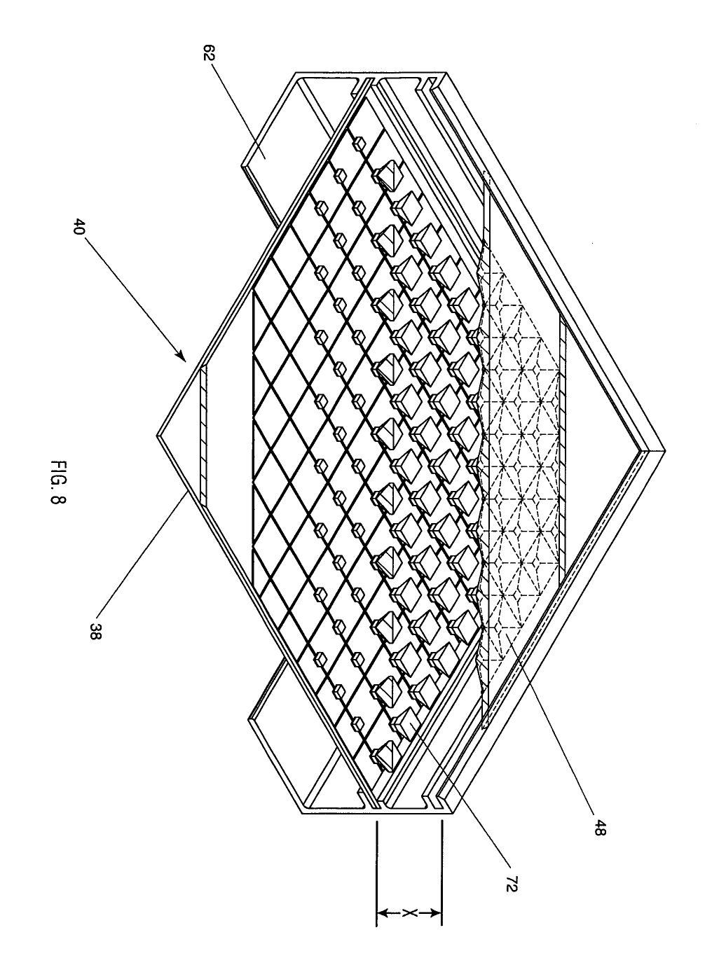

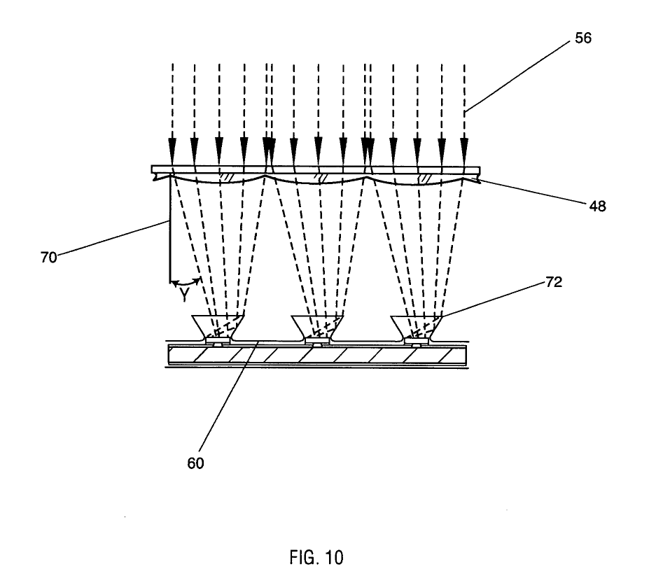

Primary lens sheet 48 has a flat side 50 and an opposing lens side 52 onto which a matrix of square lenses 54 are formed. Primary lens sheet 48 is configured similarly to a fly's eye with a matrix of many small lenses, efficiently concentrating sunlight 56 onto the corresponding matrix of PV cells 20 and provides the outer covering for the module to resist the elements such as rain, hail, dirt, etc. Aspheric primary lenses are designed to minimize the distance between lens sheet 48 and the reciever sheet assembly 46 and focus the sunlight in a circular pattern on the photoactive surface of the PV cell. Square lenses 54, as shown in FIGS. 8 and 10, are designed to focus light rays 56 as uniformaly across cell surface 22 as possible, in the same recatangular shape as the PV cell. Primary lens sheet 48, when used without a secondary optical lens, is set parallel and at a fixed distance X from reciever sheet assembly 46 to focus incident solar radiation 56 in a pattern onto cell surface 22 that is slightly smaller than cell active surface 22, so that slight errors in sun tracking will not result in some of the solar radiation beign focused on non active surfaces of reciever sheet 46. It may also be desireable to not illuminate the photoactive surface near the cut edges of the PV cell to avoid any edge affect losses from micro fractures induced during the dicing of the PV cells. A circular pattern may be more effective than a square patern depending upon the microfracture locations around the perimeter of PV cell 20. Although the primary lens sheet 48 shown is made from glass, it may be molded from plastic material such as acrylic. If plastic material is used, an anti scratch coating or a glass sheet may be bonded to the outer flat surface of the plastic material to provide a more abrasive resistant outer surface (not shown). Abrasion resistance is an important consideration since the outer surface of primary lens sheet 48 will be subject to wind blown sand and debris during long term operation. Scratches and pitting on the surface of the primary lense will decrease the optical efficiency of the lens. Also shown are PV cells 20 connected in parallel, with positive conductors 24 affixed to positive conductive paths and negative conductors 28 eletrically affixed to negative condutive path of printed circuit conductor 38.

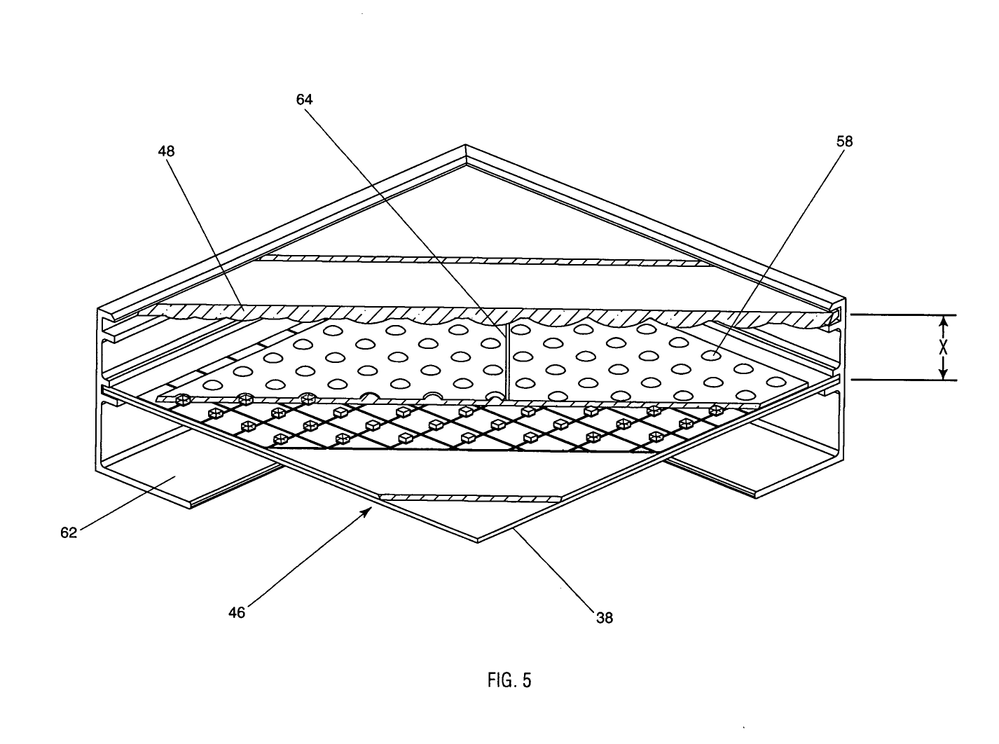

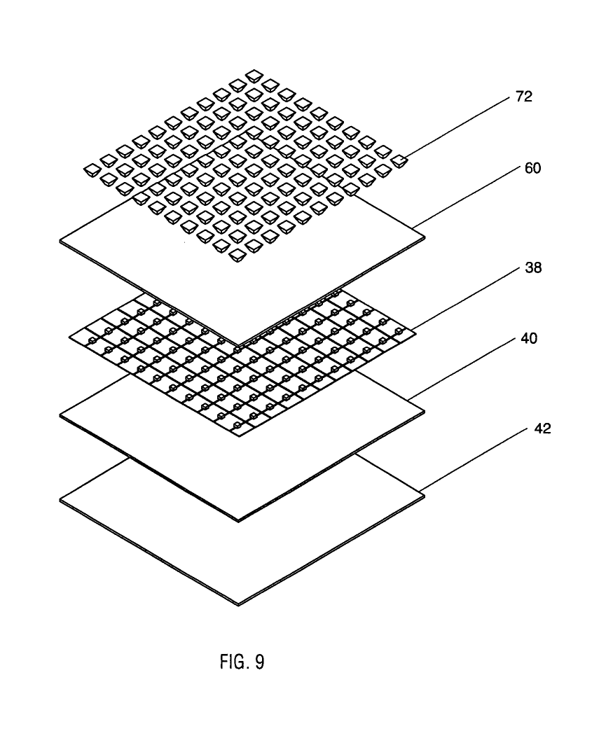

A secondary lens 58 may be formed in the encapsulant 60 or molded from a polymer, such as acrylic, and affixed by encapsulant 60 onto the active surface of PV cells 20 to uniformly distribute and homogenize the solar radiation onto the active surface of the PV cells. A rounded or circular secondary lens 58 is shown in FIG. 5. This rounded seconday lens 58 directs sunlignt 56 in a circular pattern over active surfaces 22. FIGS. 8, 9 and 10 show the embodiments with a rectangular secondary lens 72. This embodiment is similar to FIG. 5;however, a rectangular reflective secondary lens 72 is disposed between primary lens 54 and active surface 22 of PV cells 20. In addition, primary lens 54 is faceted to direct sunlight 56 in a retangular pattern to approximate the rectangular pattern of active surface 22. A reflective secondary lens 72 may also further concentrate and increase the off axis tolerance of the solar irradiation to relax the sun tracking accuracy requirements. As is shown in FIG. 10, rectangular secondary lens 72 or optical element is a light transmissive material and functions to capture the concentrated sunlight from refractive primary lens 54 and trap sunlight 56 through total internal reflection thereby channeling sunlight 56 uniformly onto photo active surface 22 of PV cell 20. An additional function of rectangular secondary lens 72 is to increase the acceptance angle of the power module, thereby reducing the solar tracking accuracy requirements. The off axis behavior of the optical system with total internal reflection secondary optical elements is shown in FIG. 10. Sunlight rays 56 enter primary lens sheet 48 at an angle Y that is not perpendicular 70 to the active surfaces 22 in the power module. The concentrated suns rays are uniformly redirected to photo active surfaces 22 of PV cells 20 through the total internal reflective properties of rectangular secondary lens 72. Rectangular secondary lenses 72 may be molded from a light transmissive material such as acrylic or glass in a matrix array to aid in placement on reciever sheet 46 of the the power module. Recatngular secondary lenses 72 may also be bonded to photoactive surfaces 22 of PV cells 20 with a light transmissive conformal coating, such as a silicone compound. Although rectangular secondary lenses 72 are shown signularly in the drawings, they can be part of a sheet as shown in FIG. 5 or affixed in an array as is well known in the art.

Transparent encapsulant layer 60 covering entire reciever sheet 46 will be applied through a thermo formed sheet or by a suitable liquid spray conformal coating. The encapsulant coating provides increased electrical isolation from the circuit of the reciever sheet and also provides environmental protection from moisture.

FIGS. 5 and 8 show cutaway views of the completed assembly in a frame. The primary lens sheet 48 and receiver sheet assembly 46 is then mounted into a frame structure 62 that serves as the structure to dispose primary lens sheet 48 and reciever sheet assembly 46 at the proper focal length distance X to achieve optimum efficiency. Frame structure 62 also serves as the mounting attachment structure for mounting the modules to a solar tracker. Insulator stand-offs 64 may be incorporated between primary lens sheet 48 and reciever sheet assembly 46 to increase the structural integrity of power module 32 and to assist in the proper alignment of the primary lens sheet 48 to reciever sheet assembly 46.

An electrical junction box with the power output electrical terminations, a fuse and bypass diodes or reverse blocking diodes, if required by the output voltage configuration, will be incorporated into the power module to provide a housing for the aformentioned components and connection to the electrical output of the solar power module (not shown). By using the embodiments as described herein, the combined thickness of primary lens sheet 48, laminated substrate 36 (with or without secondary lens 58) and the space between, comprising focal length distance X, is less than 4″.

Although the invention has been described in detail with particular reference to these preferred embodiments, other embodiments can achieve the same results. Variations and modifications of the present invention will be obvious to those skilled in the art and it is intended to cover in the appended claims all such modifications and equivalents. The entire disclosures of all references, applications, patents, and publications cited above, are hereby incorporated by reference.

1. A photovoltaic power module comprising:
a plurality of rear contact photovoltaic cells mounted on a single conductive receiver board, the conductive receiver board comprising at least one first conductive path and at least one second conductive path, the at least one first conductive path electrically isolated from the at least one second conductive path, wherein a first conductive surface of each rear contact photovoltaic cells is electrically connected to the at least one first conductive path and a second conductive surface of each rear contact photovoltaic cells is electrically connected to the at least one second conductive path; and
a primary lens sheet for concentrating light rays comprising a plurality of lenses which correspond to the plurality of rear contact photovoltaic cells, wherein each lens focuses the light rays across a photoactive surface of each rear contact photovoltaic cell.

2. The photovoltaic module of claim 1 further comprising a secondary lens sheet disposed between the primary lens sheet and the photoactive surface of each rear contact photovoltaic cell for uniformly distributing the light rays on each photovoltaic cell.

3. The photovoltaic module of claim 2 wherein the secondary lens sheet comprises a plurality of rectangular lenses for redirecting and distributing the light rays in a rectangular pattern.

4. The photovoltaic module of claim 2 wherein the secondary lens sheet comprises a plurality of circular lenses for distributing the light rays in a circular pattern.

5. The photovoltaic module of claim 2 where in the secondary lens sheet comprises reflective elements.

6. The photovoltaic power module of claim 1 wherein the receiver board comprises an encapsulated receiver board.

7. The photovoltaic power module of claim 1 wherein the receiver board comprises a printed circuit board.

8. The photovoltaic power module of claim 1 further comprising a back conductive layer for dissipating heat.

9. The photovoltaic power module of claim 1 wherein the plurality of rear contact photovoltaic cells are connected in parallel.

10. The photovoltaic power module of claim 1 wherein the plurality of rear contact photovoltaic cells are connected in series.

11. The photovoltaic power module of claim 1 wherein the plurality of rear contact photovoltaic cells comprise at least one first set of rear contact photovoltaic cells connected in parallel and electrically connected to at least one second set of rear contact photovoltaic cells connected in series configured to output a predetermined voltage.

12. The photovoltaic module of claim 1 wherein a thickness of the photovoltaic module is less than 4 inches.

13. A method of making a photovoltaic module comprising a plurality of rear contact photovoltaic cells, the method comprising the steps of:
providing a single printed circuit board comprising a pattern to corresponding to conductive surfaces on the rear contact photovoltaic cells;
testing each rear contact photovoltaic cell for a specified output;
placing the tested rear contact photovoltaic cells of the pattern of the printed circuit board;
soldering the conductive surfaces to the pattern of the printed circuit board; and
disposing a primary lens sheet for concentrating light rays on a photoactive surface of each rear contact photovoltaic cell at a predetermined distance from the photoactive surface.

14. The method of claim 13 further comprising the step of disposing a secondary lens between the primary lens and the photoactive surface.

15. The method of claim 14 further comprising the step of redirecting and distributing the concentrated light rays in a rectangular configuration.

16. The method of claim 14 further comprising the step of distributing the concentrated light rays in a circular configuration.

17. The method of claim 13 further comprising the step of encapsulating the printed circuit board after the soldering step.

18. The method of claim 13 further comprising mounting the printed circuit board and the primary lens in a frame.

19. The method of claim 13 further comprising the step of covering the primary lens with an abrasion resistant coating.

20. The method of claim 13 further comprising the step of disposing a back conductive layer on the printed circuit board for dissipating heat.

21. The method of claim 13 wherein the pattern comprises connecting the rear contact photovoltaic cells in series.

22. The method of claim 13 wherein the pattern comprises connecting the rear contact photovoltaic cells in parallel.

23. The method of claim 13 wherein the pattern comprises at least one first set of rear contact photovoltaic cells connected in parallel and electrically connected to at least one second set of rear contact photovoltaic cells connected in series, configured to output a predetermined voltage.

24. The method of claim 13 wherein the photovoltaic module comprises a thickness of less than 4 inches.
